(19) United States
(12) Patent Application Publication
(10) Pub. No.: US 2024/0337022 A1
(43) Pub. Date: Oct. 10, 2024

(54) FILM FORMING APPARATUS AND FILM FORMING METHOD

(71) Applicant: Tokyo Electron Limited, Tokyo (JP)

(72) Inventors: Kensaku NARUSHIMA, Nirasaki City (JP); Takashi KOBAYASHI, Nirasaki City (JP); Shinya OKABE, Nirasaki City (JP); Takashi SAKUMA, Nirasaki City (JP); Kunihiro TADA, Nirasaki City (JP); Satoshi YOSHIDA, Nirasaki City (JP)

(21) Appl. No.: 18/624,402

(22) Filed: Apr. 2, 2024

(30) Foreign Application Priority Data
Apr. 10, 2023 (JP) 2023-063724

(51) Int. Cl. C23C 16/509; C23C 16/14; C23C 16/44; C23C 16/455; C23C 16/46

(52) U.S. Cl. CPC C23C 16/509; C23C 16/14; C23C 16/4405; C23C 16/4408; C23C 16/45512; C23C 16/46

(57) ABSTRACT

A film forming apparatus, including a processing container, an interior of which is configured to be depressurized, an electrode configured to generate an electric field in a processing space inside the processing container, a radio frequency power supply configured to supply radio frequency power to the electrode, a stage arranged in the processing container to place a substrate thereon, and a film forming gas introduction part configured to introduce vaporized zirconium chloride into the processing space. The film forming gas introduction part is made of a metal and is grounded.

### CROSS-REFERENCE TO RELATED APPLICATION

This application is based upon and claims the benefit of priority from Japanese Patent Application No. 2023-063724, filed on Apr. 10, 2023, the entire contents of which are incorporated herein by reference.

### TECHNICAL FIELD

The present disclosure relates to a film forming apparatus and a film forming method.

### BACKGROUND

In a metal oxide semiconductor field effect transistor (MOSFET) that uses silicon (Si) or silicon germanium (SiGe), as a wiring (contact) material for a source or a drain, titanium (Ti) or titanium silicide (TiSiₓ) is used.

However, in recent years, with a further miniaturization of semiconductor devices, wiring materials with lower resistance have been demanded in order to miniaturize wiring. One factor of contact resistance between the source or drain and wiring is a Schottky barrier (SBH). Semiconductors constituting the source or drain include P-type and N-type semiconductors. However, in order to lower the SBH with respect to the N-type semiconductor, it is known to use a metal material having a conduction band whose energy level is close to a conduction band of silicon or silicon germanium. Zirconium (Zr) is known as such a metal material. Further, a zirconium film is formed on a wafer, for example, in a CVD apparatus using plasma generated by exciting and decomposing vaporized zirconium chloride (ZrCl₄) (see, for example, Patent Document 1).

### PRIOR ART DOCUMENT

### Patent Document

Patent Document 1: Japanese Patent Laid-Open Publication No. 1993-343354

### SUMMARY

According to one embodiment of the present disclosure, a film forming apparatus includes a processing container, an interior of which is configured to be depressurized, an electrode configured to generate an electric field in a processing space inside the processing container, a radio frequency power supply configured to supply radio frequency power to the electrode, a stage arranged in the processing container to place a substrate thereon, and a film forming gas introduction part configured to introduce vaporized zirconium chloride into the processing space, wherein the film forming gas introduction part is made of a metal and is grounded.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a diagram showing a configuration of a plasma processing apparatus as a film forming apparatus regarding an embodiment of a technique according to the present disclosure.

FIG. 2 is a cross-sectional view for explaining a coating structure of an exposed component in the plasma processing apparatus of FIG. 1.

FIG. 3 is a diagram for explaining a structure of a purge gas supply system in the plasma processing apparatus of FIG. 1.

FIG. 4 is a diagram schematically showing a configuration of a gas supply system of the plasma processing apparatus of FIG. 1.

FIG. 5 is a diagram for explaining reduction of a distance between a stage and a shower head in the plasma processing apparatus of FIG. 1.

FIG. 6 is a flowchart showing a flow of various processing executed when forming a zirconium film on a surface of a wafer.

FIG. 7 is a flowchart showing a film forming pre-process.

FIG. 8 is a sequence diagram showing introduction timings of various gases and supply timings of radio frequency power in a film forming process.

FIGS. 9A to 9C are process diagrams for explaining a deposition of zirconium in the film forming process.

FIGS. 10A to 10D are sequence diagrams showing introduction timings of various gases and supply timings of radio frequency power, for explaining a removal process of occluded zirconium in the film forming process.

FIG. 11 is a sequence diagram showing introduction timings of various gases and supply timings of radio frequency power in a reduction process.

FIG. 12 is a graph showing a relationship between a flow rate of a hydrogen gas and impedance of a load or tune of a matcher in the reduction process.

FIGS. 13A to 13D are flowcharts showing a cleaning process.

FIG. 14 is a diagram showing a configuration of a first modified example of the plasma processing apparatus of FIG. 1.

FIG. 15 is a diagram showing a configuration of a second modified example of the plasma processing apparatus of FIG. 1.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Zirconium chloride is normally in a solid state. In order to form a zirconium film, zirconium chloride is first heated and vaporized and is introduced into a processing container of a CVD apparatus using a carrier gas such as argon (Ar) gas. Then, vaporized zirconium chloride (hereinafter referred to as a “zirconium chloride gas”) is excited and decomposed by an electric field generated in a chamber to generate plasma.

However, since excitation and decomposition of the zirconium chloride gas requires a lot of energy, it is not easy to excite and decompose the zirconium chloride gas, and it is difficult to stably form the zirconium film using the zirconium chloride gas by a conventional CVD apparatus.

According to a technique of the present disclosure, an introduction part for introducing a zirconium chloride gas into a processing container is grounded to induce discharge from an electric field toward the introduction part. The discharge promotes excitation and decomposition of the zirconium chloride gas. In addition, by grounding, ions in the plasma are drawn into the introduction part, and the ions actively collide with individual molecules of the zirconium chloride gas to promote excitation and decomposition of the zirconium chloride gas. Thereby, a zirconium film is stably formed.

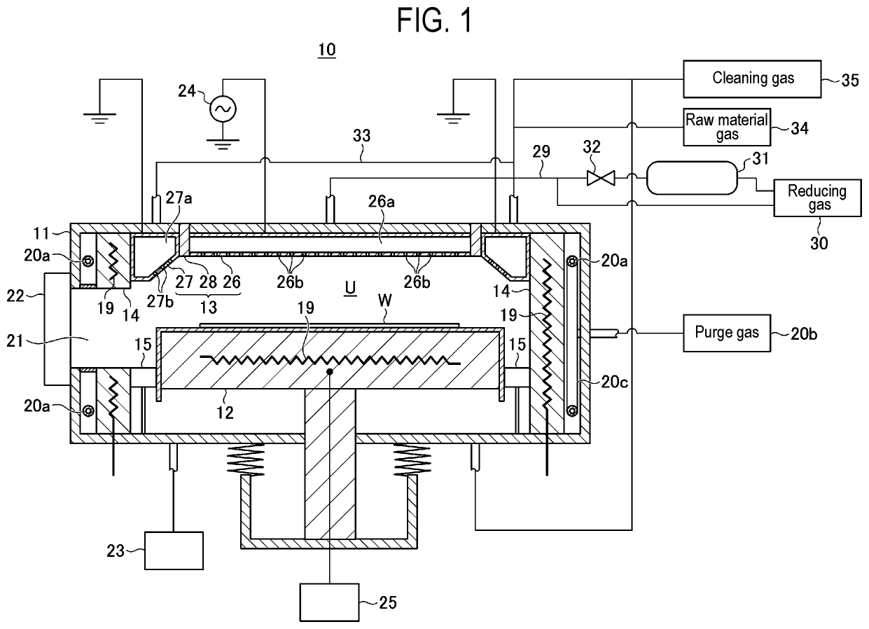

Hereinafter, one embodiment of a technique according to the present disclosure will be described with reference to the drawings. FIG. 1 is a diagram showing a configuration of a plasma processing apparatus as a film forming apparatus according to the embodiment.

In FIG. 1, a plasma processing apparatus 10 includes a substantially cylindrical chamber (processing container) 11, an interior of which is depressurized to accommodate a wafer W (substrate). A stage 12 on which the wafer W is placed is arranged in a lower side of the chamber 11, and the stage 12 is configured to be movable in a vertical direction by a drive mechanism (not shown). Further, a shower head 13 made of a metal, for example, aluminum, is arranged on a ceiling of the chamber 11. A processing space U is formed between the stage 12 and the shower head 13, and in the processing space U, zirconium chloride plasma is generated from a zirconium chloride gas, which will be described later.

Further, a wall-shaped liner 14 is arranged in the chamber 11 so as to surround the side of the processing space U, and a substantially annular baffle ring 15 configured to surround the stage 12 is arranged between the liner 14 and the stage 12. The liner 14 or the baffle ring 15 suppresses the plasma generated in the processing space U from diffusing outside the processing space U. The baffle ring 15 is provided with a plurality of through holes (not shown) to allow the processing space U and a space below the stage 12 to communicate with each other.

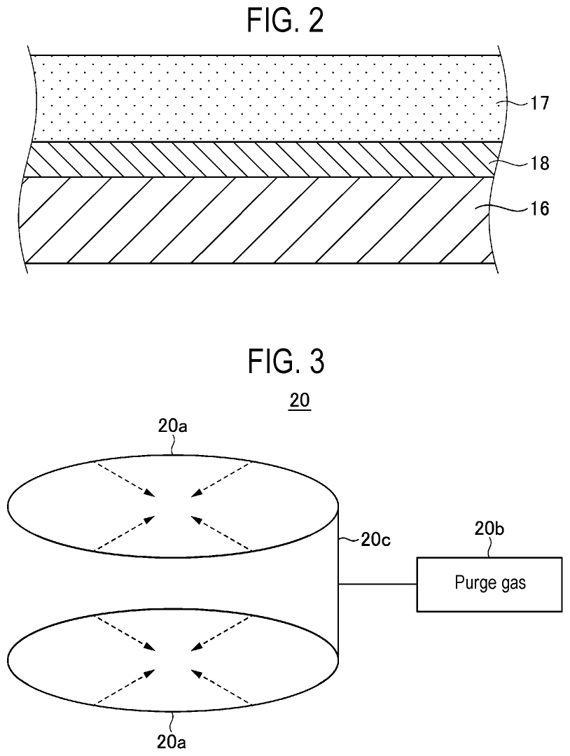

Surfaces of components, such as the stage 12, the shower head 13, and the liner 14 or the baffle ring 15, that are at least partially exposed to the processing space U (hereinafter referred to as “exposed components”) are first covered with a base layer 16 (a first coating film) made of a material that does not contain oxygen, as shown in FIG. 2. This material that does not contain oxygen is, for example, aluminum nitride (AlN). The base layer 16 prevents oxidation of a base material of the exposed component and prevents corrosion due to a chlorine gas, etc., which will be described later. Further, since the base layer 16 does not contain oxygen, even if the base layer 16 is etched by plasma, for example, oxygen is not released, and oxidation of zirconium described later can be suppressed.

The base layer 16 is covered with a sacrificial film 18 (a second coating film) made of a component that is identical or similar to a by-product 17, for example, zirconium (Zr), generated when a zirconium film is formed using the plasma in the processing space U. In addition, a heater 19 (heating mechanism) is embedded in the stage 12 or the liner 14.

The plasma processing apparatus 10 also includes an oxygen concentration monitor (not shown) that monitors the oxygen concentration of the processing space U, a plasma monitor (not shown) that monitors the state of the plasma of the processing space U, and a purge gas supply system 20 that supplies a purge gas to the inside of a chamber 11. As shown in FIG. 3, the purge gas supply system 20 includes two annular gas discharge pipes 20a, a purge gas supply source 20b, and a pipe 20c connecting each gas discharge pipe 20a and the purge gas supply source 20b. Each gas discharge pipe 20a is arranged in a space between a sidewall of the chamber 11 and the liner 14. As shown by broken lines in the figure, each gas discharge pipe 20a discharges a purge gas at each position to suppress decomposed products of the zirconium chloride gas from entering a corresponding space. This prevents the by-product 17 from attaching to an outer sidewall of the liner 14 and the sidewall of the chamber 11.

Further, the sidewall of the chamber 11 is provided with a loading/unloading port 21 for loading/unloading the wafer W into/out of the processing space U, and a gate valve 22 for opening/closing the loading/unloading port 21, and an exhaust system 23 is arranged at a bottom of the chamber 11. The exhaust system 23 includes a pump that exhausts the inside of the chamber 11, such as a turbo molecular pump or a dry pump (not shown), and an exhaust valve that controls an internal pressure of the chamber 11, such as an automatic pressure controller (APC) valve (not shown). When generating plasma in the processing space U, the exhaust system 23 lowers the pressure of the processing space U to, for example, several tens of mTorr.

The shower head 13 has a substantially disc-shaped reducing gas introduction part 26 and a substantially annular raw material gas introduction part 27 (film forming gas introduction part). The raw material gas introduction part 27 is arranged to surround the reducing gas introduction part 26, and an insulating member 28 is arranged between the raw material gas introduction part 27 and the reducing gas introduction part 26.

The reducing gas introduction part 26 has a gas diffusion chamber 26a formed therein, and a plurality of gas holes 26b through which the gas diffusion chamber 26a and the processing space U communicate with each other. The raw material gas introduction part 27 also has a gas diffusion chamber 27a formed therein, and a plurality of gas holes 27b through which the gas diffusion chamber 27a and the processing space U communicate with each other. Further, the reducing gas introduction part 26 faces the wafer W placed on the stage 12, but the raw material gas introduction part 27 does not face the wafer W placed on the stage because the raw material gas introduction part 27 is arranged to surround the reducing gas introduction part 26.

A reducing gas supply source 30 is connected to the reducing gas introduction part 26 via a pipe 29, and the reducing gas supply source 30 supplies a hydrogen gas as a reducing gas to the gas diffusion chamber 26a. The hydrogen gas supplied to the gas diffusion chamber 26a is introduced into the processing space U through the gas holes 26b. Further, the pipe 29 branches into two systems between the reducing gas introduction part 26 and the reducing gas supply source 30, and a fill tank 31 (reducing gas storage tank) is arranged in one system. Further, a valve 32 is arranged between the fill tank 31 and the reducing gas introduction part 26. The fill tank 31 stores a reducing gas supplied from the reducing gas supply source 30 and supplies the stored reducing gas to the gas diffusion chamber 26a in a short time when the valve 32 is opened.

A raw material gas supply source 34 is connected to the raw material gas introduction part 27 via a pipe 33, and the raw material gas supply source 34 supplies a zirconium chloride gas as a raw material gas to the gas diffusion chamber 27a. The zirconium chloride gas supplied to the gas diffusion chamber 27a is introduced into the processing space U via the gas holes 27b.

Further, a cleaning gas supply source 35 is connected to the pipe 29 or the pipe 33. The cleaning gas supply source 35 supplies a chlorine gas as a cleaning gas to the gas diffusion chambers 26a and 27a. The cleaning gas supplied to the gas diffusion chambers 26a and 27a is introduced into the processing space U via the gas holes 26b and 27b.

Further, in the plasma processing apparatus 10, in addition to the above-described reducing gas supply source 30, raw material gas supply source 34, and cleaning gas supply source 35, various gas supply sources are connected to the gas diffusion chambers 26a and 27a via the pipes 29 and 33.

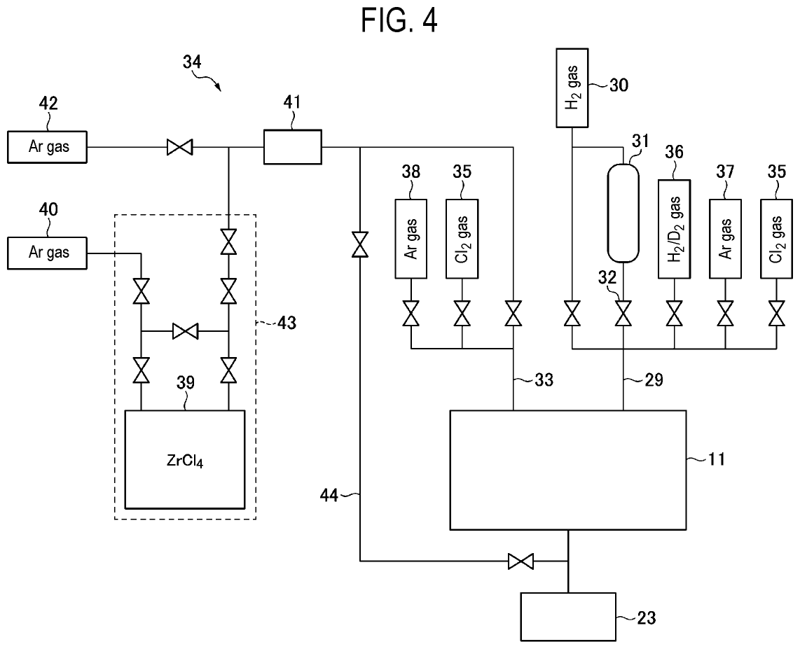

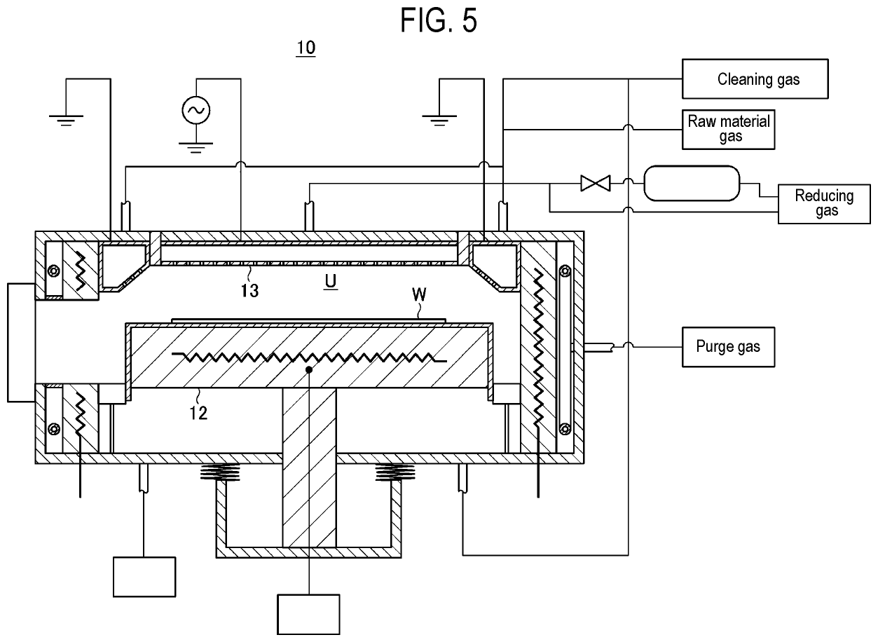

FIG. 4 is a diagram schematically showing a configuration of a gas supply system of the plasma processing apparatus 10 of FIG. 1. In the embodiment, since a hydrogen (H₂) gas is used as a reducing gas, the reducing gas supply source 30 is expressed as an “H₂ gas” in the figure. Further, since a chloride gas that does not contain fluorine, specifically, a chlorine (Cl₂) gas, is used as a cleaning gas, the cleaning gas supply source 35 is expressed as a “Cl₂ gas” in the figure. The cleaning gas is not limited to the chlorine gas and, for example, a hydrogen chloride (HCl) gas, a boron trichloride (BCl₃) gas, a zirconium chloride (IV) (ZrCl₄) gas, and a titanium chloride (IV) (TiCl₄) gas may be used.

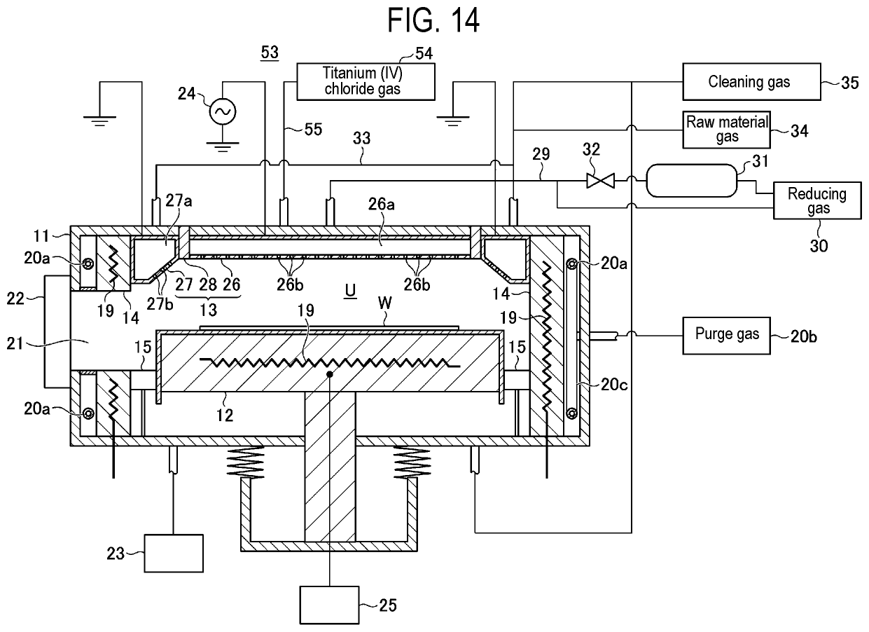

In FIG. 4, in addition to the above-described reducing gas supply source 30, raw material gas supply source 34, or cleaning gas supply source 35, an argon (Ar) gas supply source and a hydrogen/deuterium (H₂/D₂) gas source are connected to the gas diffusion chambers 26a and 27a of the plasma processing apparatus 10. In the figure, the argon gas supply source is expressed as an “Ar gas,” and the hydrogen/deuterium gas supply source is expressed as an “H₂/D₂ gas.” Further, in the case of forming a titanium (Ti) film in the plasma processing apparatus 10, a titanium chloride (IV) gas supply source is connected to the gas diffusion chamber 26a (see FIG. 14 which will be described later).

Specifically, in addition to the reducing gas supply source 30, the fill tank 31, or the cleaning gas supply source 35, a hydrogen/deuterium gas supply source 36 and an argon gas supply source 37 are connected to the gas diffusion chamber 26a via the pipe 29. Further, in addition to the raw material gas supply source 34 or the cleaning gas supply source 35, an argon gas supply source 38 is connected to the gas diffusion chamber 27a via the pipe 33.

In FIG. 4, a detailed configuration of the raw material gas supply source 34 is shown. In FIG. 4, the raw material gas supply source 34 includes an accommodation container (ampoule) 39 for accommodating powdered zirconium chloride and an argon gas supply source 40 connected to the ampoule 39. The raw material gas supply source 34 also includes a mass flow meter (MFM) 41 disposed between the ampoule 39 and the chamber 11, an argon gas supply source 42 directly connected to the MFM 41, and a heater 43 surrounding the ampoule 39. The raw material gas supply source 34 has an Evac pipe 44 that branches from the pipe 33 between the MFM 41 and the chamber 11 and reaches the exhaust system 23 without passing through the chamber 11.

When performing a film forming process to be described later, the heater 43 generates a zirconium chloride gas by heating and vaporizing zirconium chloride contained in the ampoule 39 to 140 degrees C. to 200 degrees C. The argon gas supply source 40 supplies an argon gas as a carrier gas to the inside of the ampoule 39. The supplied argon gas attracts the zirconium chloride gas and is discharged from the ampoule 39. Then, the argon gas attracting the zirconium chloride gas reaches the chamber 11 via the MFM 41 by the argon gas as the carrier gas supplied from the argon gas supply source 42 and is introduced into the gas diffusion chamber 27a. The zirconium chloride gas or the argon gas introduced into the gas diffusion chamber 27a is introduced into the processing space U through the gas holes 27b. In the film forming process, the argon gas functions not only as a carrier gas, but also as a diluent gas or a partial pressure adjustment gas of the zirconium chloride gas.

When performing a reduction process to be described later, the reducing gas supply source 30 supplies the hydrogen gas to the gas diffusion chamber 26a via the pipe 29. However, in this case, the argon gas supply source 37 also supplies the argon gas to the gas diffusion chamber 26a via the pipe 29. The hydrogen gas or the argon gas supplied to the gas diffusion chamber 26a is introduced into the processing space U through the gas holes 26b. In the reduction process as well, the argon gas functions only as a carrier gas but also as functions as a diluent gas or a partial pressure adjustment gas of the hydrogen gas.

Further, when performing the reduction process, the hydrogen/deuterium gas supply source 36 may supply a mixed gas of a hydrogen gas and a deuterium gas to the gas diffusion chamber 26a via the pipe 29. Even in this case, the argon gas supply source 37 supplies the argon gas to the gas diffusion chamber 26a via the pipe 29. In addition, the reducing gas supply source 30 supplies the hydrogen gas to the gas diffusion chamber 26a, and at the same time, the hydrogen/deuterium gas supply source 36 may supply the mixed gas of the hydrogen gas and the deuterium gas to the gas diffusion chamber 26a.

When performing a cleaning process to be described later, the cleaning gas supply source 35 supplies a chlorine gas to the gas diffusion chambers 26a and 27a via the pipes 29 and 33. In this case, the argon gas supply sources 37 and 38 also supply the argon gas to the gas diffusion chambers 26a and 27a via the pipes 29 and 33. The chlorine gas and the argon gas supplied to the gas diffusion chambers 26a and 27a are introduced into the processing space U via the respective gas holes 26b and 27b. Further, in the cleaning process as well, the argon gas functions not only as a carrier gas, but also as a diluent gas or a partial pressure adjustment gas of the chlorine gas.

Further, although the argon gas has been used as the carrier gas in the gas supply system of the plasma processing apparatus 10, other inert gases, for example, noble gases, may be used as the carrier gas.

As described above, the raw material gas introduction part 27 or the reducing gas introduction part 26 of the shower head 13 is made of, for example, aluminum. However, the raw material gas introduction part 27 is grounded, whereas a radio frequency power supply 24 is connected to the reducing gas introduction part 26. Therefore, in the embodiment, the reducing gas introduction part 26 functions as an electrode. Further, a matcher 25 such as a plasma optimizer (POP) is connected to the stage 12. The radio frequency power supply 24 generates an electric field in the processing space U by supplying a radio frequency power of, for example, 450 kHz, for plasma generation (hereinafter referred to simply as a “radio frequency power”) to the reducing gas introduction part 26. The matcher 25 maintains the electric field generated in the processing space U by changing the potential of the stage 12. The electric field generated in the processing space U excites and decomposes the hydrogen gas or the zirconium chloride gas introduced into the processing space U to generate hydrogen plasma and zirconium chloride plasma.

In the film forming process, the zirconium chloride plasma is generated from the zirconium chloride gas, and the zirconium chloride plasma reaches the surface of the wafer W to form a zirconium film. Further, in the reduction process, the hydrogen plasma is generated from the hydrogen gas, and the hydrogen plasma reaches the surface of the wafer W or the surface of the exposed component to reduce the surfaces of the wafer W or each exposed component.

As described above, the stage 12 is configured to be movable in the vertical direction. Further, when performing the reduction process, the stage 12 is raised and the distance between the stage 12 and the shower head 13 is smaller than when performing the film forming process. Specifically, when performing the reduction process, the distance between the stage 12 and the shower head 13 is set to, for example, 5 mm.

Further, the plasma processing apparatus 10 is provided with a controller (not shown). The controller includes a computer having at least a CPU and a memory, and a recipe (program) for executing the film forming process or the reduction process is recorded in the memory.

However, as described above, it is not easy to excite and decompose the zirconium chloride gas. In the plasma processing apparatus 10, the raw material gas introduction part 27 that introduces the zirconium chloride gas into the processing space U is grounded. Therefore, when the electric field is generated in the processing space U, a self-bias is generated in the raw material gas introduction part 27, and the potential of the raw material gas introduction part 27 decreases. As a result, ions in the plasma are drawn into the raw material gas introduction part 27 and actively collide with individual molecules of the zirconium chloride gas existing around the raw material gas introduction part 27 to promote the excitation and decomposition of the zirconium chloride gas.

Furthermore, since the raw material gas introduction part 27 is grounded, arc discharge is likely to occur from the electric field in the processing space U toward the raw material gas introduction part 27. Then, the energy of individual molecules of the zirconium chloride gas existing around the raw material gas introduction part 27 increases by receiving the arc discharge. This also promotes the excitation and decomposition of the zirconium chloride gas.

As a result, it is easy to generate the zirconium chloride plasma from the zirconium chloride gas, and a large amount of the zirconium chloride plasma is generated, so that the zirconium film can be stably formed on the surface of the wafer W. In addition, since the zirconium film formed in this case is stable, peeling or the like is difficult to occur, and it is possible to suppress part of the zirconium film from scattering as particles, thereby preventing particles from attaching to the exposed components.

However, by-products generated from the zirconium chloride gas may attach to the vicinity of the gas holes 27b of the raw material gas introduction part 27 and there is a risk of the by-products falling off. However, in the plasma processing apparatus 10, since the raw material gas introduction part 27 does not face the wafer W placed on the stage 12, the fallen by-products can be prevented from attaching to the surface of the wafer W.

Further, for example, in a case where the by-product 17 deposited on the surface of each exposed component cannot be completely removed by the cleaning process described below, the exposed component is separated from the chamber 11 and the by-product 17 is removed using a chemical solution. In this case, if only the by-product 17 is removed, the sacrificial film 18 with a rough surface remains on the exposed component.

However, as described above, in the plasma processing apparatus 10, since the sacrificial film 18 is made of a component which is identical or similar to the by-product 17, the sacrificial film 18 can also be removed with the chemical solution for removing the by-product 17. That is, since not only the by-product 17 but also the sacrificial film 18 can be removed by the chemical solution, no rough surface remains on the exposed component when the by-product 17 is removed. In addition, since not only the by-product 17 but also the sacrificial film 18 can be removed with one type of chemical solution, it is possible to eliminate the necessity of cleaning the exposed component with several types of chemical solutions and the exposed component (particularly, the base layer 16) can be suppressed from being damaged by the chemical solution. The sacrificial film 18 is regenerated by thermal spray or the like on the surface of the exposed component (base layer 16) from which the by-product 17 or the sacrificial film 18 has been removed by the chemical solution.

In the plasma processing apparatus 10, the heater 19 is embedded in the stage 12 or the liner 14, as described above. When performing the film forming process, the heater 19 heats the stage 12 or the liner 14. As a result, even if the by-product 17 attaches to the stage 12 or the liner 14, impurities in the by-product 17 can be removed by sublimation or the like, and the impurities contained in the by-product 17 can be reduced. As a result, the by-product 17 can be easily removed using the chlorine gas or the chemical solution.

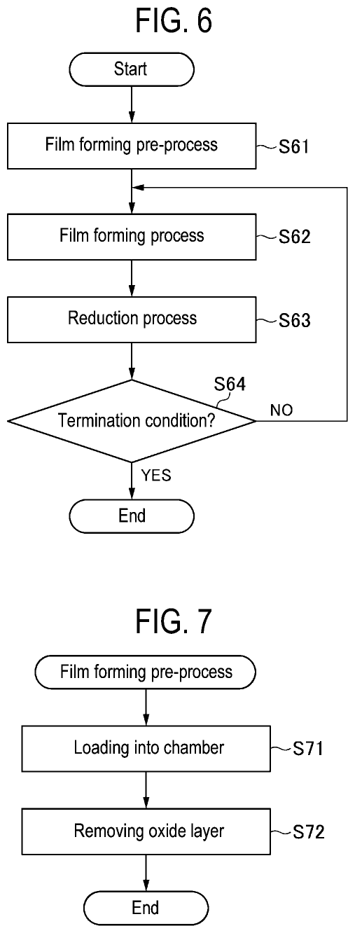

Next, various processing executed by the plasma processing apparatus 10 will be described. FIG. 6 is a flowchart showing a flow of various processing executed when forming a zirconium film on the surface of the wafer W. Various processing is realized by the controller executing a recipe recorded in the memory.

In FIG. 6, the plasma processing apparatus 10 first performs a film forming pre-process of removing a natural oxide film of the wafer W (Step S61) and performs the film forming process of forming a zirconium film on the surface of the wafer W (Step S62).

Next, the reduction process of reducing the formed zirconium film is performed (Step S63), and it is determined whether a termination condition is satisfied (Step S64). If the termination condition is not satisfied, the process returns to Step S62, and if the termination condition is satisfied, the processing is ended. The termination condition in the process in FIG. 6 is, for example, whether the number of repetitions of the reduction process (Step S63) has reached a predetermined number of times.

In addition to the process of FIG. 6 described above, the plasma processing apparatus 10 also performs the cleaning process of removing the by-product 17 from the exposed component. The various processing will be described in detail below.

First, a film forming pre-process will be described. Typically, before the wafer W is loaded into the plasma processing apparatus 10 by a transfer device such as a transfer module, a natural oxide film formed on a silicon surface of the wafer W is removed using plasma in a plasma processing apparatus different from the plasma processing apparatus 10. However, small amounts of oxygen may be present inside a depressurized transfer module. In this case, when the wafer W is transferred from another plasma processing apparatus to the plasma processing apparatus 10, the small amounts of oxygen may be adsorbed to the surface of a source or a drain made of silicon, for example, in a semiconductor device, and thus an oxide layer may be formed. Therefore, in the embodiment, before performing the film forming process, the film forming pre-process is performed to remove the formed oxide layer by reduction or the like.

FIG. 7 is a flowchart showing the film forming pre-process. In FIG. 7, first, the wafer W is loaded into the chamber 11 from the loading/unloading port 21, and the wafer W is placed on the stage 12 (Step S71). Next, the interior of the chamber 11 is depressurized by the exhaust system 23, and a hydrogen gas or an argon gas is introduced into the processing space U from the reducing gas supply source 30 or the argon gas supply sources 37 and 38 via the gas diffusion chambers 26a and 27a. Further, the radio frequency power supply 24 supplies radio frequency power to the reducing gas introduction part 26 to generate an electric field in the processing space U. In this case, hydrogen plasma or argon plasma generated from the hydrogen gas or the argon gas excited and decomposed by the electric field removes an oxide layer by sputtering or a reduction reaction (Step S72). Then, after a predetermined time has elapsed, this processing is ended.

In the process of FIG. 7, plasma is generated not only from the argon gas but also from the hydrogen gas, and the formed oxide layer is removed using not only sputtering but also the reduction reaction. However, if the formed oxide layer is extremely thin, only the argon gas or the hydrogen gas may be introduced into the processing space U and the formed oxide layer may be removed using only the plasma generated from either of the argon gas and the hydrogen gas.

In the embodiment, prior to the film forming pre-process in the plasma processing apparatus 10, the natural oxide film formed on the silicon surface of the wafer W is removed in another plasma processing apparatus. Thereby, in the plasma processing apparatus 10, it is not necessary to remove a large amount of natural oxide film, and it is possible to prevent a large amount of oxygen generated when removing the natural oxide film from remaining in the processing space U. As a result, the zirconium film formed in the film forming process after the film forming pre-process can be suppressed from being oxidized in the chamber 11.

Further, it is not always necessary to use plasma to remove the natural oxide film formed on the silicon surface of the wafer W. For example, before the wafer W is loaded into the plasma processing apparatus 10 by the transfer device such as the transfer module, the natural oxide film may be removed by a plasma-less process in an oxide removal apparatus different from the plasma processing apparatus 10. In this oxide removal apparatus, the natural oxide film is removed by a plasma-less chemical oxide removal (COR) process based on a chemical reaction using a hydrogen fluoride (HF) gas and an ammonia (NH₃) gas.

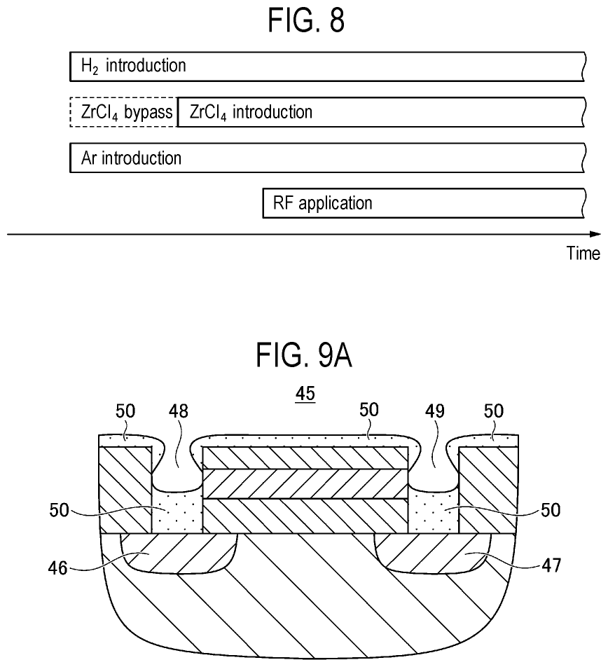

Next, the film forming process will be described. FIG. 8 is a sequence diagram showing introduction timings of various gases and supply timings of radio frequency power in the film forming process. When radio frequency power is supplied to the reducing gas introduction part 26, since a radio frequency (RF) voltage is applied from the reducing gas introduction part 26 to the processing space U, the supply of radio frequency power is expressed as “RF application” in FIG. 8.

In the film forming process, first, the hydrogen gas or the argon gas is introduced into the processing space U from the reducing gas supply source 30 or the argon gas supply source 37 via the gas diffusion chamber 26a while maintaining an internal state of the chamber 11 that has been depressurized in the film forming pre-process. At the same time, in the raw material gas supply source 34, the heater 43 heats powdered zirconium chloride accommodated in the ampoule 39 to generate a zirconium chloride gas, and the argon gas supply source 40 supplies the argon gas to the inside of the ampoule 39.

The argon gas attracting the zirconium chloride gas passes through the MFM 41, but is not guided to the chamber 11 by the pipe 33 and flows through the Evac pipe 44 until a predetermined time has elapsed after the start of the film forming process. As a result, the argon gas attracting the zirconium chloride gas bypasses the chamber 11, reaches the exhaust system 23, and is exhausted from the plasma processing apparatus 10.

Thereafter, if a predetermined time has elapsed, the argon gas attracting the zirconium chloride gas is guided to the chamber 11 by the pipe 33 and introduced into the processing space U via the gas diffusion chamber 27a. Whether the argon gas attracting the zirconium chloride gas is allowed to flow through the pipe 33 or the Evac pipe 44 is controlled by opening and closing each valve arranged in the pipe 33 or the Evac pipe 44.

Next, if a predetermined time has elapsed, the zirconium chloride gas has spread throughout the processing space U, and the state of the processing space U is stabilized, the radio frequency power supply 24 supplies radio frequency power to the reducing gas introduction part 26. Thereby, an electric field is generated in the processing space U, and the electric field excites and decomposes the zirconium chloride gas introduced into the processing space U to generate zirconium chloride plasma. At this time, the zirconium chloride plasma reaches the surface of the wafer W to form a zirconium film. Further, the temperature of the wafer W at this time is maintained at 300 degrees C. or higher by the heater of the stage 12. Further, the hydrogen gas introduced into the processing space U reduces the zirconium chloride gas to promote decomposition into chlorine or zirconium.

Here, since the zirconium chloride gas is generated by heating and vaporizing powdered zirconium chloride, for a while after starting to heat zirconium chloride, zirconium chloride is not fully warmed and a stable amount is not generated. Further, while the entire zirconium chloride is not completely warmed, the powdered zirconium chloride attracted by the argon gas may flow out from the ampoule 39. However, in the embodiment, as shown in FIG. 8, the argon gas attracting the zirconium chloride gas flowing out from the ampoule 39 flows through the Evac pipe 44 until a predetermined time has elapsed from the start of the film forming process. This can prevent a shortage of the zirconium chloride gas introduced into the processing space U and prevent the zirconium chloride in a powder form from flowing into the processing space U.

In each MOSFET 45 existing on the surface of the wafer W, a via hole 48 opens toward a source 46 and a via hole 49 opens toward a drain 47. When forming the zirconium film, the zirconium chloride gas dissociated or activated by the zirconium chloride plasma enters the via holes 48 and 49, and zirconium 50 is deposited.

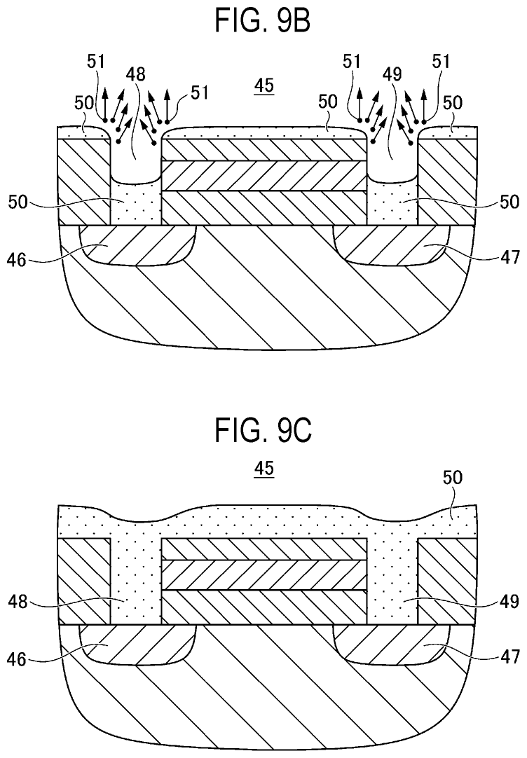

However, with further miniaturization of a semiconductor device, aspect ratios of the via holes 48 and 49 have increased. Thereby, the zirconium chloride gas dissociated or activated by the zirconium chloride plasma tends to attach to entrances of the via holes 48 and 49 before reaching bottoms of the via holes 48 and 49. As a result, as shown in FIG. 9A, the zirconium 50 is deposited near the entrances of the via holes 48 and 49, and the deposited zirconium 50 may block the entrances of the via holes 48 and 49. In this case, the zirconium chloride gas dissociated or activated by the zirconium chloride plasma cannot sufficiently enter interiors of the via holes 48 and 49, and the zirconium 50 is not firmly deposited inside the via holes 48 and 49. As a result, wiring formed in the via holes 48 and 49 may contain defects such as voids. Therefore, in the embodiment, when performing the film forming process, the zirconium 50 deposited near the entrances of the via holes 48 and 49 (hereinafter referred to as “occluded zirconium”) is removed.

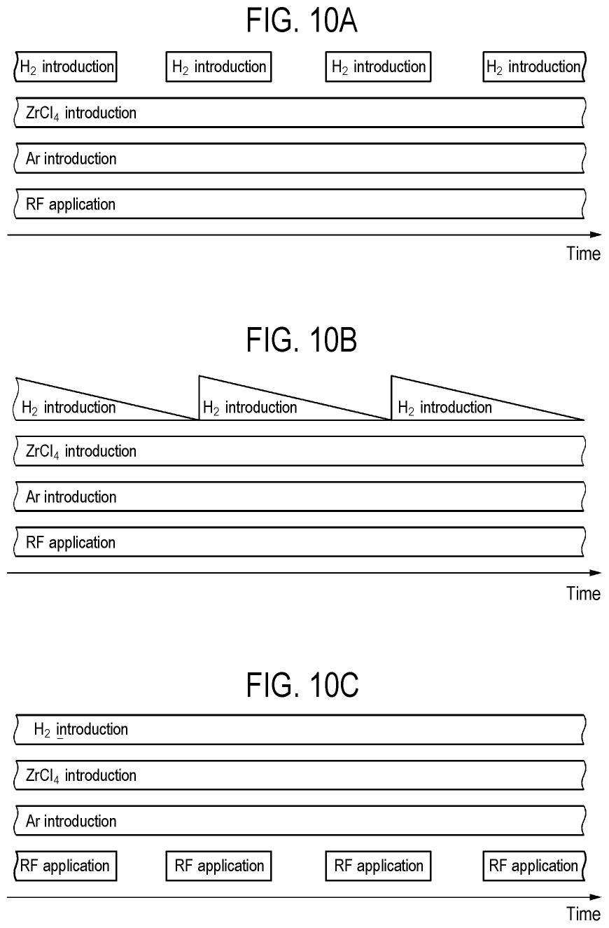

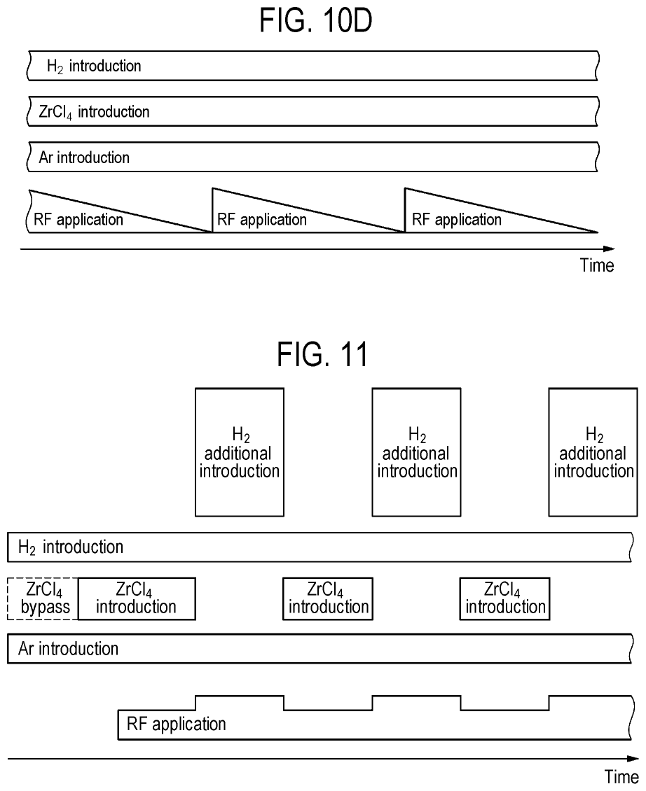

FIGS. 10A to 10D are sequence diagrams showing introduction timings of various gases and supply timings of radio frequency power, for explaining a removal process of occluded zirconium in the film forming process.

In the film forming process, if an amount of a hydrogen gas introduced into the processing space U is reduced, decomposition into chlorine and zirconium due to reduction of a zirconium chloride gas becomes stagnant, and even if an electric field is generated in the processing space U, there is a high possibility that the zirconium chloride gas will not be decomposed and will remain as it is. The remaining zirconium chloride gas chemically reacts with the occluded zirconium and transforms into a zirconium chloride (III) (ZrCl₃) 51, but the zirconium chloride (III) 51 is easily vaporized to the same degree as zirconium chloride (IV) (ZrCl₄). Therefore, the occluded zirconium becomes the zirconium chloride (III) 51 and then vaporizes and scatters (FIG. 9B). That is, if the amount of the hydrogen gas introduced into the processing space U is reduced, the occluded zirconium can be removed, and the zirconium chloride gas dissociated or activated by the zirconium chloride plasma can sufficiently enter the insides of the via holes 48 and 49. As a result, the zirconium 50 can be firmly deposited inside the via holes 48 and 49 (FIG. 9C). The zirconium chloride gas that chemically reacts with the zirconium 50 includes both the zirconium chloride gas that is excited and becomes plasma while maintaining zirconium chloride and the zirconium chloride gas that is not excited and exists as a gas.

Therefore, in this embodiment, in order to remove the occluded zirconium, the amount of the hydrogen gas introduced into the processing space U during the film forming process is reduced. For example, as shown in FIG. 10A, the hydrogen gas is intermittently introduced into the processing space U. In this case, when the hydrogen gas is not introduced into the processing space U, the occluded zirconium is removed by the zirconium chloride gas, and when the hydrogen gas is introduced into the processing space U, the zirconium 50 is deposited in the via holes 48 and 49. That is, in the via holes 48 and 49, the deposition of the zirconium 50 and the removal of the occluded zirconium are repeated. Thereby, the zirconium chloride gas dissociated or activated by the zirconium chloride plasma can certainly enter the insides of the via holes 48 and 49 without being obstructed by the occluded zirconium. As a result, the zirconium 50 is firmly deposited inside the via holes 48 and 49, and wiring formed in the via holes 48 and 49 can be prevented from containing defects such as voids.

Further, in order to reduce the amount of the hydrogen gas introduced into the processing space U while the film forming process is performed, for example, as shown in FIG. 10B, the flow rate of hydrogen gas introduced into the processing space U may be gradually reduced repeatedly. In this case, when the flow rate of the hydrogen gas introduced into the processing space U decreases, the occluded zirconium is removed by the zirconium chloride gas, and when the flow rate of the hydrogen gas introduced into the processing space U increases, the zirconium 50 is deposited in the via holes 48 and 49. That is, as in the case of FIG. 10A, since the deposition of the zirconium 50 and the removal of the occluded zirconium are repeated in the via holes 48 and 49, wiring formed in the via holes 48 and 49 can be suppressed from including defects such as voids.

Further, in the film forming process, when radio frequency power supplied to the reducing gas introduction part 26 is weakened, an electric field in the processing space U is also weakened, and decomposition into chlorine and zirconium due to excitation of the zirconium chloride gas becomes stagnant. Then, the zirconium chloride gas remaining without being decomposed chemically reacts with the occluded zirconium and transforms into the zirconium chloride (III) 51, thereby removing the occluded zirconium. That is, if the radio frequency power supplied to the reducing gas introduction part 26 is weakened, the occluded zirconium can be removed and the zirconium chloride gas dissociated or activated by the zirconium chloride plasma can sufficiently enter the insides of the via holes 48 and 49. As a result, similarly to the case in which the hydrogen gas introduced into the processing space U is reduced, the zirconium 50 can be certainly deposited inside the via holes 48 and 49.

Therefore, in this embodiment, the radio frequency power supplied to the reducing gas introduction part 26 may be weakened in order to remove the occluded zirconium. For example, as shown in FIG. 10C, the radio frequency power is intermittently supplied to the reducing gas introduction part 26. In this case, when the radio frequency power is not supplied to the reducing gas introduction part 26, the occluded zirconium is removed by the zirconium chloride gas, and when the radio frequency power is supplied to the reducing gas introduction part 26, the zirconium 50 is deposited in the via holes 48 and 49. That is, as in the case of FIG. 10A, since the deposition of the zirconium 50 and the removal of the occluded zirconium are repeated in the via holes 48 and 49, wiring formed in the via holes 48 and 49 can be suppressed from containing defects such as voids.

Additionally, in order to weaken the radio frequency power supplied to the reducing gas introducing part 26 while the film forming process is executed, for example, as shown in FIG. 10D, the radio frequency power supplied to the reducing gas introduction part 26 may be gradually decreased repeatedly. In this case, when the radio frequency power supplied to the reducing gas introduction part 26 is weakened, the occluded zirconium is removed by the zirconium chloride gas, and when the radio frequency power supplied to the reducing gas introduction part 26 is strengthened, the zirconium 50 is deposited in the via holes 48 and 49. That is, as in the case of FIG. 10A, since the deposition of the zirconium 50 and the removal of the occluded zirconium are repeated in the via holes 48 and 49, wiring formed in the via holes 48 and 49 can be suppressed from containing defects such as voids.

In the film forming process, while the argon gas is supplied to the inside of the ampoule 39 in order to transport the zirconium chloride gas, there is a possibility that unvaporized powdered zirconium chloride may be attracted when the flow rate of the supplied argon gas suddenly increases. The attracted powdered zirconium chloride may reach the MFM 41 and each valve of the pipe 33, thereby causing malfunction thereof.

Therefore, in this embodiment, pressure inside the ampoule 39 is monitored, and the argon gas supply source 40 is controlled such that the internal pressure of the ampoule 39 does not rapidly increase, that is, the flow rate of the argon gas flowing into the ampoule 39 does not increase suddenly. Specifically, the flow rate of the argon gas from the argon gas supply source 40 is adjusted so that an internal pressure fluctuation of the ampoule 39 falls within a predetermined range. This suppresses the powdered zirconium chloride from being attracted inside the ampoule 39 and prevents the powdered zirconium chloride from reaching the MFM 41 and each valve of the pipe 33.

Next, the reduction process will be described. In the embodiment, in the film forming process, the zirconium chloride gas is excited and decomposed to generate zirconium chloride plasma. However, since chlorine is generated at the same time, there is a possibility that a chlorine component remains in wiring of the source 46 and drain 47 formed from the zirconium 50. Moreover, since the zirconium 50 is very easily oxidized, if even a small amount of oxygen is present in the processing space U, the zirconium 50 immediately reacts with oxygen, and the surface of the zirconium 50 is easily covered with an oxide film. If the oxide film remains, wiring resistance of the source 46 and drain 47 formed from the zirconium 50 increases, and the MOSFET 45 may not achieve desired performance. Therefore, in order to reduce and remove the chlorine component or the oxide film, the reduction process is performed in the embodiment.

FIG. 11 is a sequence diagram showing introduction timings of various gases and supply timings of radio frequency power in the reduction process. As shown in the flowchart of FIG. 6, the film forming process and the reduction process are repeatedly performed in the embodiment. However, the introduction of a zirconium chloride gas into the process space U is stopped during the reduction process. Therefore, in FIG. 11, a timing when the zirconium chloride gas is not introduced corresponds to the reduction process.

As shown in FIG. 11, even at a timing of performing the reduction process, the supply of radio frequency power to the reducing gas introduction part 26 continues. Therefore, in the reduction process, the hydrogen gas introduced into the processing space U is excited and decomposed to generate hydrogen plasma. This hydrogen plasma reduces and removes an oxide film of the zirconium 50 deposited on the surface of the wafer W or a chlorine component contained in the deposited zirconium 50 in the film forming process.

When performing the reduction process in the embodiment, in order to promote the reduction of the chlorine component or the oxide film, the hydrogen gas introduced into the processing space U is additionally supplied and the flow rate of the hydrogen gas introduced into the processing space U is increased as compared to when the film forming process is performed, thereby increasing the hydrogen plasma. Specifically, when performing the reduction process, the valve 32 is opened to supply the hydrogen gas not only from the reducing gas supply source 30 but also from the fill tank 31 to the gas diffusion chamber 26a of the reducing gas introduction part 26. This increases the flow rate of the hydrogen gas introduced into the processing space U from each gas diffusion chamber 26a. In this case, the flow rate of the hydrogen gas introduced into the processing space U is set to 10 L/minute or more. Further, since the flow rate of the hydrogen gas increases, the pressure of the processing space U is maintained at 10 mTorr or more.

In order to ensure dissociation and decomposition of the increased hydrogen gas, the radio frequency power supplied to the reducing gas introduction part 26 is strengthened to strengthen an electric field. In this case, the potential of the stage 12 is adjusted by changing the impedance of a load or tune, which is a variable capacitor of the matcher 25, to prevent the radio frequency power from being reflected from the reducing gas introduction part 26.

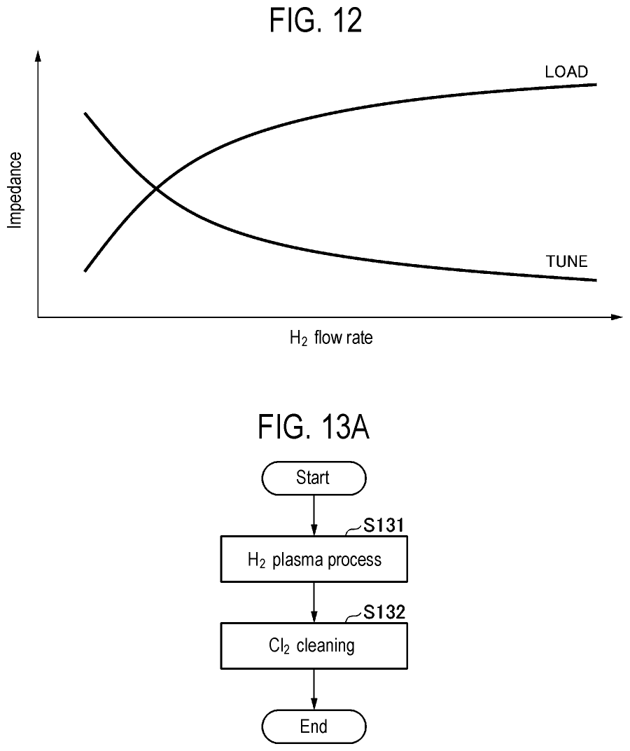

The controller of the plasma processing apparatus 10 pre-stores a relationship between the impedance of the load or tune of the matcher 25 and the flow rate of the hydrogen gas introduced into the processing space U, as shown in FIG. 12, for example. Then, the controller determines the impedance of the load or tune of the matcher 25 according to this relationship. The controller may store the relationship between the impedance of the load or tune of the matcher 25 and the pressure of the fill tank 31 or store the relationship between the impedance of the load or tune of the matcher 25 and the internal pressure of the chamber 11.

In the embodiment, the reduction process is repeatedly performed, and as a result, the oxide film of the zirconium 50 and the chlorine component contained in the zirconium 50 are removed before being covered with the new zirconium 50. As a result, it is possible to prevent the oxide film and the chlorine component from remaining in the wiring of the source 46 and drain 47, and it is possible to prevent the MOSFET 45 from failing to achieve desired performance.

In addition, when performing the reduction process, in order to further increase reducing power, the hydrogen gas and the deuterium gas may be introduced into the process space U from the hydrogen/deuterium gas supply source 36 to generate not only hydrogen plasma but also deuterium plasma. When the hydrogen gas and the deuterium gas are introduced into the processing space U from the hydrogen/deuterium gas supply source 36, the hydrogen gas may be introduced into the processing space U from the reducing gas supply source 30 or the fill tank 31, or the introduction of the hydrogen gas from the reducing gas supply source 30 or the fill tank 31 may be stopped.

In this embodiment, as described above, when performing the reduction process, the stage 12 is raised and the distance between the stage 12 and the shower head 13 becomes shorter than when the film forming process is performed. Thereby, the density of the hydrogen plasma in the processing space U can be increased, and the reducing power can be increased.

When the surface of the zirconium 50 is easily covered with the oxide film so that the reduction process is required, it is considered that oxygen concentration of the processing space U has been increased. Therefore, the oxygen concentration of the processing space U is monitored by an oxygen concentration monitor, and when the oxygen concentration of the processing space U exceeds a predetermined oxygen concentration, the reduction process of Step S63 may be executed.

Next, the cleaning process will be described. In the embodiment, the cleaning process is performed independently of the film forming pre-process, the film forming process, or the reduction process. In the cleaning process according to the embodiment, the by-product 17 deposited on the surface of the exposed component, which is a cause of occurrence of particles, is removed.

However, a main component of the by-product 17 is zirconium. Typically, a chlorine trifluoride (ClF₃) gas is used in the cleaning process of an exposed component. However, since a saturated vapor pressure of zirconium fluoride (ZrF₄), which is produced by reaction between the chlorine trifluoride gas and zirconium, is low, it is difficult for zirconium fluoride to be vaporized. Therefore, in the plasma processing apparatus 10 that forms a zirconium film, it is difficult to remove the by-product 17 deposited on the exposed component even if the cleaning process is performed using the chlorine trifluoride gas. On the other hand, zirconium chloride has a higher saturated vapor pressure than zirconium fluoride and is easily vaporized. Therefore, in the embodiment, a chloride gas that does not contain fluorine, for example, a chlorine gas, is reacted with the by-product 17 to produce zirconium chloride in the cleaning process, and the by-product 17 is removed by vaporizing this zirconium chloride. In addition to the chlorine gas, chloride gases such as a hydrogen chloride gas, a boron trichloride gas, a titanium chloride (IV) gas, and a zirconium chloride (IV) gas can be used for the cleaning process. Further, a gas that does not contain fluorine and contains chlorine can be used for the cleaning process.

As described above, since the main component of the by-product 17 deposited on the surface of the exposed component is zirconium, if even a small amount of oxygen is present in the processing space U, the surface of the by-product 17 reacts with this oxygen and may be covered with an oxide film. This oxide film inhibits reaction between the chlorine gas and the by-product 17. Therefore, in the embodiment, before introducing the chloride gas that does not contain fluorine, for example, the chlorine gas, into the processing space U, the oxide film covering the surface of the by-product 17 is reduced by a reduction reaction.

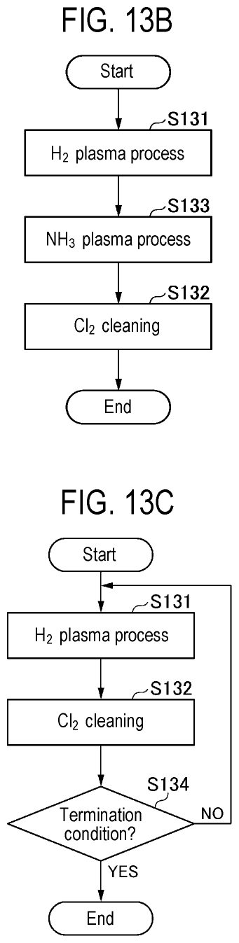

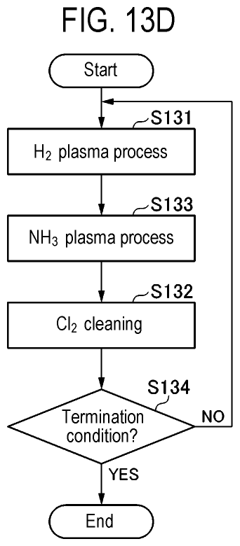

FIGS. 13A to 13D are flowcharts showing the cleaning process. In the embodiment, the cleaning process is executed when an accumulated value of execution times of the film forming process exceeds a predetermined time.

In the cleaning process, for example, as shown in FIG. 13A, a hydrogen gas is first introduced into the processing space U from the reducing gas supply source 30, and an electric field is generated in the processing space U. The hydrogen gas is excited and decomposed to generate hydrogen plasma. This hydrogen plasma reduces an oxide film covering the surface of the by-product 17 (Step S131).

Next, a chloride gas that does not contain fluorine, for example, a chlorine gas, is introduced from the cleaning gas supply source 35 into the processing space U via the gas diffusion chamber 26a of the reducing gas introduction part 26 or the gas diffusion chamber 27a of the raw material gas introduction part 27. In this case, the chlorine gas reacts with the by-product 17 deposited on the surface of the exposed component to produce zirconium chloride. The generated zirconium chloride is easily vaporized because the inside of the chamber 11 is in a depressurized state. As a result, the by-product 17 is removed (Step S132). Thereafter, the processing is ended.

If there are many deposited by-products 17, when introducing the chlorine gas into the processing space U in Step S132, an electric field may be generated in the processing space U to excite and decompose the chlorine gas and generate chlorine plasma. Since the chlorine plasma has higher energy than the chlorine gas, the chlorine plasma reacts more actively with the by-products 17. Therefore, even if there are many deposited by-products 17, all the by-products 17 can be changed to zirconium chloride, and the by-products 17 can be completely removed.

Further, since an ammonia gas also has strong reducing power, the ammonia gas may be used together with the hydrogen gas when reducing the oxide film covering the surface of the by-product 17. For example, as shown in FIG. 13B, after Step S131 is first executed, the ammonia gas is introduced into the processing space U from an ammonia gas supply source (not shown), and an electric field is generated in the processing space U. The ammonia gas is excited and decomposed to generate ammonia plasma. This ammonia plasma also reduces the oxide film covering the surface of the by-product 17 (Step S133). Next, Step S132 is executed to remove the by-product 17, and then the processing is ended.

In order to completely remove the by-product 17, Step S131 or Step S132 may be repeated. For example, as shown in FIG. 13C, after Step S131 and Step S132 are executed, it is determined whether a termination condition of the cleaning process is satisfied (Step S134). If the termination condition is not satisfied, the process returns to Step S131, and Steps S131 and S132 are executed again. If the termination condition is satisfied, the processing is ended.

Further, when the ammonia gas is used together with the hydrogen gas, Steps S131 to S133 may be repeated. For example, as shown in FIG. 13D, after Step S131, Step S133, and Step S132 are executed, it is determined whether a termination condition of the cleaning process is satisfied (Step S134). If the termination condition is not satisfied, the process returns to Step S131, and Steps S131 to S132 are executed again, and if the termination condition is satisfied, the processing is ended.

The termination condition of Step S134 is, for example, whether the number of times of execution of Step S132 exceeds a predetermined number of times. Further, since oxygen is generated when removing the by-product 17, in Step S134, it may be determined whether the termination condition of the cleaning process is satisfied by monitoring oxygen concentration of the processing space U by the oxygen concentration monitor. In this case, it is determined that the termination condition is satisfied if there are few by-products 17 to be removed, so that no oxygen is generated, and the oxygen concentration of the processing space U is below a predetermined oxygen concentration.

Although exemplary embodiments of the present disclosure have been described above, the present disclosure is not limited to the embodiments described above, and various modifications and changes can be made within the scope of the gist of the present disclosure.

For example, in this embodiment, while the wiring for the source 46 and the drain 47 is formed of zirconium, the wiring may be formed of zirconium silicide (ZrSi₂).

Alternatively, the wiring for the source 46 and drain 47 may be formed of titanium silicide (TiSiₓ), zirconium chloride plasma may be generated in the processing space U, and then titanium silicide may be doped with zirconium by the zirconium chloride plasma. In this case, since the main component of the by-product 17 deposited on the surface of the exposed component is titanium (Ti) rather than zirconium, the sacrificial film 18 is desirably formed of titanium or titanium nitride (TiN).

Further, after forming the wiring for the source 46 and drain 47 with zirconium silicide, a titanium film may be formed on zirconium silicide, or zirconium film formation and titanium film formation may be repeated. In particular, by forming the titanium film on zirconium silicide, a silicon component of zirconium silicide is attracted by titanium to form titanium silicide.

As a method of forming titanium on zirconium silicide, a titanium film is formed by a CVD process in which a titanium chloride (IV) gas and a hydrogen gas are supplied into the chamber 11 to generate plasma from these gases after forming zirconium silicide. In this method, a plasma processing apparatus 53 shown in FIG. 14 is used. The plasma processing apparatus 53 has the same configuration as the plasma processing apparatus 10 but differs from the plasma processing apparatus 10 in that the plasma processing apparatus 53 includes a titanium chloride (IV) gas supply source 54. In the plasma processing apparatus 53, the titanium chloride (IV) gas supply source 54 is connected to the gas diffusion chamber 26a of the reducing gas introduction part 26 via a pipe 55. Then, a titanium chloride (IV) gas and a hydrogen gas which serves as a reducing gas, mixed in the gas diffusion chamber 26a, are introduced into the processing space U, and an electric field of the processing space U excites and decomposes the titanium chloride (IV) gas to generate titanium chloride plasma. This titanium chloride plasma forms the titanium film on zirconium silicide.

As described above, since the plasma processing apparatus 53 has the same configuration as the plasma processing apparatus 10, the formation of the zirconium film and the formation of the titanium film can be performed in the same chamber 11. This eliminates the need to form the zirconium film and the titanium film in separate chambers 11 and reduces the number of chambers 11 to avoid an increase in the size and number of plasma processing apparatuses, thereby suppressing an increase in footprint.

Further, in the shower head 13 of the plasma processing apparatus 10, the hydrogen gas has been introduced into the processing space U from the reducing gas introduction part 26, and the zirconium chloride gas has been introduced into the processing space U from the raw material gas introduction part 27. That is, the hydrogen gas and the zirconium chloride gas have been separately introduced into the processing space U.

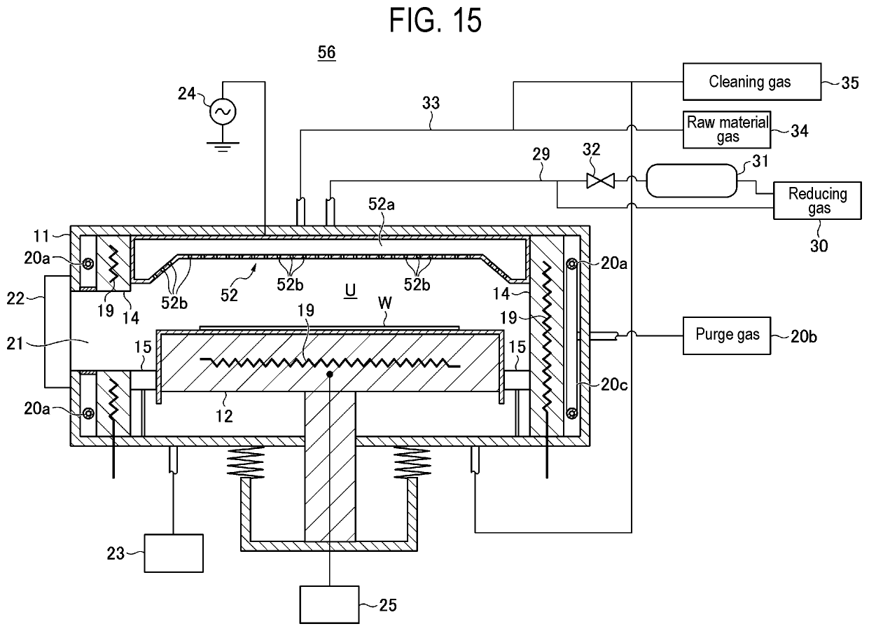

However, the zirconium chloride gas and the hydrogen gas may be mixed in advance before being introduced into the processing space U. In this case, the plasma processing apparatus 56 includes a shower head 52 instead of the shower head 13, as shown in FIG. 15.

The shower head 52 has the same external shape as the shower head 13 and has a gas diffusion chamber 52a formed therein and a plurality of gas holes 52b through which the gas diffusion chamber 52a and the processing space U communicate with each other. The reducing gas supply source 30 is connected to the shower head 52 via the pipe 29, and the raw material gas supply source 34 is connected to the shower head 52 via the pipe 33. Therefore, the hydrogen gas supplied from the reducing gas supply source 30 and the zirconium chloride gas supplied from the raw material gas supply source 34 are mixed in the gas diffusion chamber 52a before being introduced into the processing space U. Thereafter, the mixed hydrogen gas and zirconium chloride gas are introduced into the processing space U via the gas holes 52b.

At this time, since the hydrogen gas exists near the zirconium chloride gas in the processing space U, the zirconium chloride gas excited by plasma immediately comes into contact with the hydrogen gas and is reduced by the hydrogen gas to promote decomposition into chlorine or zirconium. As a result, zirconium chloride plasma is easily generated. Further, the gas holes 27b are provided over a wide range of the surface of the shower head 52 facing the processing space U. Therefore, since the zirconium chloride gas is introduced from the shower head 52 into the processing space U over a wide range, an area in which the zirconium chloride gas and the plasma come into contact increases. From this point of view, the excitation and decomposition of the zirconium chloride gas is promoted, making it easier to generate the zirconium chloride plasma.

As described above, even when the plasma processing apparatus 56 includes the shower head 52, a large amount of zirconium chloride plasma can be generated to stably form the zirconium film on the surface of the wafer W.

Further, in the plasma processing apparatus 10, when performing the film forming process, the heater 19 heats an exposed component such as the stage 12 or the liner 14 to reduce impurities contained in the by-product 17. Conversely, the exposed component may be maintained at a low temperature, for example, below 120 degrees C. In this case, reaction that produces the by-product 17 does not proceed on the surface of the exposed component, and the by-product 17 can be suppressed from being deposited on the surface of the exposed component. As a method of maintaining the exposed components at a low temperature, in a case where a heater is embedded in the exposed component, it is sufficient to stop heating by the heater, and in a case where a cooling mechanism such as a chiller is embedded in the exposed component, the exposed component is cooled by the cooling mechanism.

In the film forming pre-process, while the hydrogen plasma has been generated in the processing space U after the wafer W is loaded into the chamber 11, the hydrogen plasma may be generated in the processing space U before the wafer W is loaded into the chamber 11. In this case, oxygen that generates a natural oxide film on the surfaces of a source or a drain can be removed from the inside of the chamber 11 in advance by a reduction reaction, and the natural oxide film can be suppressed from being generated.

While the oxygen concentration monitor is used to determine the termination condition of the cleaning process, the oxygen concentration monitor may also be used to detect an end point of the film forming pre-process or the reduction process. Since oxygen is generated when the oxide film is removed in the film forming pre-process or the reduction process, when oxygen is no longer generated, it can be considered that the oxide film has been removed. Therefore, in the film forming pre-process or the reduction process, oxygen concentration of the processing space U is monitored by the oxygen concentration monitor, and when the oxygen concentration of the processing space U falls below a predetermined oxygen concentration, it may be determined that the film forming pre-process or the reduction process should be ended.

According to the present disclosure in some embodiments, it is possible to stably form the zirconium layer.

While certain embodiments have been described, these embodiments have been presented by way of example only and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A film forming apparatus, comprising:
a processing container, an interior of which is configured to be depressurized;
an electrode configured to generate an electric field in a processing space inside the processing container;
a radio frequency power supply configured to supply radio frequency power to the electrode;
a stage arranged in the processing container to place a substrate thereon; and
a film forming gas introduction part configured to introduce vaporized zirconium chloride into the processing space,
wherein the film forming gas introduction part is made of a metal and is grounded.

2. The film forming apparatus of claim 1, further comprising a disc-shaped reducing gas introduction part configured to introduce a reducing gas into the processing space,
wherein the reducing gas introduction part is arranged to face the substrate placed on the stage, and
wherein the film forming gas introduction part has an annular shape and is arranged to surround the reducing gas introduction part.

3. The film forming apparatus of claim 2, wherein the film forming gas introduction part is arranged so as not to face the substrate placed on the stage.

4. The film forming apparatus of claim 2, further comprising a reducing gas storage tank configured to store the reducing gas and supply the stored reducing gas to the reducing gas introduction part.

5. The film forming apparatus of claim 1, further comprising an oxygen concentration monitor configured to monitor an oxygen concentration of the processing space.

6. The film forming apparatus of claim 1, wherein a first coating film configured to cover a surface of a component that is at least partially exposed to the processing space is made of a material that does not contain oxygen.

7. The film forming apparatus of claim 6, wherein a second coating film configured to cover the first coating film is made of a material that is identical or similar to a by-product generated when a zirconium film is formed.

8. The film forming apparatus of claim 1, further comprising a component configured to suppress plasma generated in the processing space from diffusing outside the processing space.

9. The film forming apparatus of claim 1, further comprising a purge gas supply system configured to supply a purge gas for suppressing plasma generated inside the processing container from diffusing outside the processing space.

10. The film forming apparatus of claim 1, further comprising a heating mechanism configured to heat a component that is at least partially exposed to the processing space.

11. A film forming method in a film forming apparatus,
wherein the film forming apparatus comprises a processing container, an interior of which is configured to be depressurized, an electrode configured to generate an electric field in a processing space inside the processing container, a radio frequency power supply configured to supply radio frequency power to the electrode, a stage arranged in the processing container to place a substrate thereon, and a film forming gas introduction part configured to introduce vaporized zirconium chloride into the processing space, and
wherein the film forming method comprises introducing the vaporized zirconium chloride into the processing space from the film forming gas introduction part and grounding the film forming gas introduction part, when generating plasma from the vaporized zirconium chloride by the electric field.

12. The film forming method of claim 11, wherein a reducing gas is introduced into the processing space when the plasma is generated from the vaporized zirconium chloride.

13. The film forming method of claim 12, wherein, when the plasma is generated from the vaporized zirconium chloride, a timing during which the reducing gas is not introduced into the processing space is provided while the vaporized zirconium chloride is introduced into the processing space.

14. The film forming method of claim 11, wherein a timing during which the radio frequency power is not supplied to the electrode is provided when the vaporized zirconium chloride is introduced into the processing space.

15. The film forming method of claim 11, wherein a component that is at least partially exposed to the processing space is heated when the plasma is generated from the vaporized zirconium chloride.

16. The film forming method of claim 11, wherein the film forming apparatus further comprises an accommodation container configured to accommodate powdered zirconium chloride, and
wherein, when a carrier gas carrying the vaporized zirconium chloride is introduced into the accommodation container, a flow rate of the carrier gas is adjusted such that an internal pressure fluctuation of the accommodation container falls within a predetermined range.

17. The film forming method of claim 11, wherein a reducing gas is introduced into the processing space and a reduction process is performed on a zirconium film formed on the substrate.

18. The film forming method of claim 17, wherein the vaporized zirconium chloride is not introduced into the processing space when the reduction process is performed on the zirconium film formed on the substrate.

19. The film forming method of claim 17, wherein the reduction process is performed when an oxygen concentration of the processing space exceeds a predetermined value by monitoring the oxygen concentration.

20. The film forming method of claim 17, wherein the reducing gas is introduced to the processing space both when the plasma is generated from the vaporized zirconium chloride and when the reduction process is performed, and
wherein the reducing gas introduced into the processing space is additionally supplied when the reduction process is performed.

21. The film forming method of claim 20, wherein the radio frequency power supplied to the electrode is strengthened when the reducing gas introduced into the processing space is additionally supplied.

22. The film forming method of claim 11, wherein, before the plasma is generated from the vaporized zirconium chloride, a reducing gas is introduced into the processing space to generate plasma from the reducing gas.

23. The film forming method of claim 12, wherein the reducing gas and the vaporized zirconium chloride are mixed in advance and then the mixed gases are introduced into the processing space.

24. The film forming method of claim 17, wherein a pressure of the processing space is maintained at 10 mTorr or more when the reduction process is performed, and a flow rate to the processing space in the reduction process is set to 10 L/minute or more.

25. The film forming method of claim 17, wherein the electrode and the stage are arranged to face each other, and configured such that a distance between the electrode and the stage can be shortened when the reduction process is performed.

26. The film forming method of claim 17, wherein the reducing gas is at least one of a hydrogen gas or a deuterium gas.

27. The film forming method of claim 11, wherein a cleaning process is performed on an inside of the processing container by introducing a cleaning gas into the processing container.

28. The film forming method of claim 27, wherein an oxide film reduction process of reducing an oxide film of a by-product generated when a zirconium film is formed on the substrate is performed before the cleaning process is performed.

29. The film forming method of claim 27, wherein the cleaning gas is a chloride gas that does not contain fluorine.
